(19) United States
(12) Patent Application Publication
(10) Pub. No.: US 2020/0161526 A1
(43) Pub. Date: May 21, 2020

(54) HEAT EXCHANGER

(71) Applicant: Mahle International GmbH, Stuttgart (DE)

(72) Inventors: Juergen Gruenwald, Ludwigsburg (DE); Christian Heneka, Karlsruhe (DE)

(21) Appl. No.: 15/999,526

(22) PCT Filed: Feb. 14, 2017
(86) PCT No.: PCT/EP2017/053284

§ 371 Date: Aug. 17, 2018

(30) Foreign Application Priority Data
Feb. 17, 2016 (DE) 10 2016 202 435.3

(51) Int. Cl. H01L 35/30; H01L 35/14; H01L 35/32; H01L 23/38; H01L 23/46; H01L 23/367

(52) U.S. Cl. CPC H01L 35/30; H01L 35/14; H01L 23/3672; H01L 23/38; H01L 23/46; H01L 35/32

(57) ABSTRACT

A heat exchanger may include a flow chamber able to be flowed through by a first fluid, a fin structure arranged in the flow chamber, a heat transfer chamber, and a thermoelectric temperature-control system. The temperature-control system may include at least one Peltier element with a plurality of p-doped p-type semiconductors and a plurality of n-doped n-type semiconductors electrically contacting one another. On a side of the fin structure, a plurality of connecting structures may be arranged. A respective connecting structure may include an electrically insulating base layer and an electrically conductive connecting layer. The fin structure may include the base layer. The connecting layer may be applied on a side of the base layer facing away from the fin structure. One such p-type semiconductor and one such n-type semiconductor may be mounted on the connecting layer. The fin structure may be provided with the base layer via oxidation.

### CROSS-REFERENCE TO RELATED APPLICATIONS

This application claims priority to International Patent Application No. PCT/EP2017/053284, filed on Feb. 14, 2017, and German Patent Application No. DE 10 2016 202 435.3, filed on Feb. 17, 2016, the contents of both of which are hereby incorporated by reference in their entirety.

### TECHNICAL FIELD

The present invention relates to a heat exchanger comprising a fin structure and a thermoelectric temperature-control system. The invention relates furthermore to an assembly of a heat exchanger of this type with a temperature-control system of this type and with a fin structure of this type.

### BACKGROUND

Heat exchangers usually serve for the exchange of heat with a fluid. Here, it is conceivable to provide the heat exchanger with an electric heat source. The disadvantage, here, is that in the operation of such heat sources a dissipative heat generation is brought about, leading to a comparatively low efficiency and/or a comparatively high energy consumption.

Basically, it is conceivable to provide heat exchangers with a fin structure, which are arranged in a flow chamber through which the fluid flows, with which the heat exchange takes place. Such fin structures are usually made from metal sheets and serve for better exchange of heat with the fluid, and therefore increase in particular the efficiency of the heat exchanger.

A better efficiency of the heat exchanger and/or an alternative configuration of the heat exchanger can be realised in general by the use of a thermoelectric temperature-control system with a Peltier element, which realizes a heat exchange in a known manner in the sense of a “pumping” of the heat. Such Peltier elements comprise here a plurality of semiconductors which are to be electrically contacted to one another in a particular manner. This requires, on the one hand, the electrical contacting of particular semiconductor elements to one another, and on the other hand the electrical insulating of other semiconductor elements with respect to one another. In order, in particular, to prevent an undesired short-circuit of the Peltier element, it is therefore usual to configure the Peltier element so as to be electrically insulating at opposite ends. For this, usually electrically insulating plates come into use, owing to their advantageous heat conductivity characteristics, in particular ceramic plates. Such plates are, however, comparatively rigid structures which, in the case of corresponding thermal load, in particular in the case of great and/or rapid temperature changes, can lead to thermal stresses and damage to the Peltier element or respectively to the temperature-control system. In addition, such plates constitute a thermal barrier, which have a negative effect on the efficiency of the temperature-control system. This also applies to ceramic plates which have comparatively good thermal conductivities.

A heat exchanger is known from DE 10 2009 058 550 A1 which has two fin structures. Between the fin structures a Peltier element is arranged, which has semiconductor elements. The semiconductor elements are electrically contacted via electrical bridges, which are electrically insulated from one another by means of a filler body.

Heat exchangers with Peltier elements and fin structures are also known from U.S. Pat. No. 3,635,037 A and US 2003/0102554 A1.

### SUMMARY

The present invention is therefore concerned with the problem of indicating, for a heat exchanger of the type mentioned in the introduction, and for an assembly of such a heat exchanger, improved or at least different embodiments which are distinguished in particular by an increased efficiency and/or an improved lifespan and/or an increased capacity.

This problem is solved according to the invention by the subject matter of the independent claim(s). Advantageous embodiments are the subject matter of the dependent claim(s).

The present invention is based on the general idea, in a heat exchanger comprising a fin structure and a thermoelectric temperature-control system having at least one Peltier element, of mounting semiconductors of the Peltier element onto the fin structure and of electrically insulating them from the fin structure by a base layer. The semiconductors of the Peltier element are therefore mounted directly on the fin structure, so that in particular the deformable, in particular elastically deformable, characteristic of the fin structure is used in order to arrange the semiconductors of the Peltier element accordingly movably relative to one another. Consequently, during operation of the heat exchanger or respectively of the Peltier element, an improved adaptation of the Peltier element to thermal changes is brought about, in particular improved mechanical contractions and/or expansions. The capacity and the lifespan of the Peltier element and therefore of the heat exchanger are therefore improved. Furthermore, through the use of the base layer for electrical insulation, separate plates for electrical insulation can be dispensed with, so that a heat exchange of the Peltier element is improved and the efficiency is therefore increased.

In accordance with the idea of the invention, the heat exchanger has here a flow chamber which is able to be flowed through by a fluid, which is designated below as first fluid. The fin structure is arranged in this flow chamber and is able to be flowed through by the first fluid. The first fluid exchanges heat with a heat transfer chamber, wherein between the fin structure and the heat transfer chamber, which is preferably fluidically separated from the flow chamber, a thermoelectric temperature-control system is arranged for the transmission of heat between the heat transfer chamber and the flow chamber. The thermoelectric temperature-control system has at least one such Peltier element, wherein the Peltier element has a plurality of semiconductors, namely p-doped p-type semiconductors and n-doped n-type semiconductors. The electrically insulating base layer is a component part of a connecting structure, which has in addition an electrically conductive connecting layer. Here, the connecting structure is arranged on the side of the fin structure facing the Peltier element. According to the invention, the base layer is provided on the fin structure, whereas the connecting layer is applied on the side of the base layer facing away from the fin structure. This means that the base layer electrically insulates the connecting layer with respect to the fin structure. On the connecting layer, such a p-type semiconductor and such an n-type semiconductor are mounted for the electrical contacting of these semiconductors, wherein these semiconductors are arranged on the side of the connecting layer facing away from the base layer. This means that the electrical contacting of the p-type semiconductor with the n-type semiconductor takes place via the connecting layer, which is insulated electrically from the fin structure by means of the base layer. Therefore, the semiconductors can move with the fin structure in the case of thermomechanical loads, and consequently in particular thermal stresses can be prevented or at least reduced. Accordingly, said extended lifespan and increased capacity of the Peltier element and therefore of the heat exchanger is achieved. In addition, the heat exchange takes place via the fin structure, which is usually metalliferous and therefore offers improved heat exchange possibilities and consequently leads to an improved efficiency of the Peltier element and accordingly of the associated temperature-control system or respectively of the heat exchanger. Several such connecting structures are provided here, wherein via the respective connecting structure such a p-type semiconductor and such an n-type semiconductor are electrically contacted to one another.

The fin structure is preferably produced from a metal or a metal alloy. In particular, it is conceivable to produce the fin structure from aluminium or from an aluminium alloy or respectively from copper or from a copper alloy.

A possibly necessary electrical contacting of the semiconductors on the side lying opposite the connecting layer can basically be configured in any desired manner. For this, for example, respectively an electrical connecting element, for example an electrically conductive plate element and suchlike can come into use.

A possible further necessary electrical contacting of the fin structure can basically be configured in any desired manner. It is conceivable, for example, to electrically contact different fin structures to one another in the flow chamber. It is also conceivable to electrically contact these fin structures by means of an electrical connection running on the side of the semiconductors facing away from the fin structure.

The base layer can basically be a layer connected to the fin structure. It is preferred here if the base layer is connected to the fin structure in a materially bonded manner, for example glued. Alternatively or additionally, the connection can be based at least partly on chemical bonds and/or on types of physical connection, e.g. mechanical clawing.

According to the invention, the base layer is provided by an oxidation on the fin structure. This means that the fin structure is provided by a corresponding oxidation with the base layer. It is conceivable, for example, to apply the base layer onto the fin structure by an oxidizing reaction, in particular to coat the fin structure with a corresponding oxidation. Such a coating of the fin structure with the base layer leads in particular to the production of an electrically insulating layer which can be very thin, for example in the region of a few μm thick. Such a base layer therefore offers a sufficiently high electrical insulation and at the same time, in particular through the thin configuration, a comparatively small barrier for the heat exchange.

Embodiments prove to be advantageous in which the base layer, in particular through the corresponding connection with the fin structure, has comparable expansion- and contraction characteristics with the fin structure, which lead to a stable connection between the base structure and the fin structure and therefore between the semiconductors and the fin structure. A correspondingly thermally stable connection is therefore achieved between the fin structure and the base layer, which leads to a correspondingly movable arrangement of the semiconductors.

Embodiments are also preferred in which the fin structure is provided with the base layer by a reduction-oxidation reaction. This means that the base layer is connected to the fin structure by a reduction-oxidation reaction. Hereby, also, a stable connection is brought about between the base layer and the fin structure, wherein the base layer advantageously has expansion- and/or contraction characteristics comparable with the fin structure, which lead to a corresponding stability in the case of temperature change, in particular in the case of thermomechanical loads.

The oxidizing or respectively the application of the reduction-oxidation reaction leads, in addition, to the formation of a correspondingly electrically insulating layer of the metalliferous fin structure. Therefore an oxidized layer is produced locally onto the fin structure.

It is particularly preferred here if the base layer is produced through the oxidation or the reduction-oxidation reaction of the fin structure per se. This means that the base layer is realized in that the fin structure is oxidized locally in the region of the base layer or is subjected to a reduction-oxidation reaction. Such a base layer is therefore provided integrally on the fin structure. In addition, no separate connection of the base layer to the fin structure is necessary hereby.

The base layer can be, for example, anodized onto the fin structure, in so far as the fin structure is produced from aluminium or contains aluminium.

Basically, such a shared base layer can be associated with at least two such connecting layers. This means that such a base layer electrically insulates at least two such connecting layers with respect to the fin structure. It is conceivable here to provide the fin structure on the side facing the semiconductors entirely or at least in substantial regions of the connecting structures entirely with the base layer. This facilitates the providing of the fin structure with the at least one base layer. In addition, hereby the risk of short-circuits between the connecting layer and the fin structure is at least reduced.

The fin structure can also be provided respectively with such a base layer only in regions of the connecting layers. In this case, therefore in particular such a base layer of its own is associated with the respective connecting layer, which base layer is separate from the base layer of other connecting layers. It is preferred here if the base layer is larger, in particular has a greater cross-section, than the connecting layer. Hereby, in particular short-circuits between the connecting layer and the fin structure are prevented or are at least reduced. Therefore, an improved thermal adaptation of the base layers is also achieved, because these do not adapt themselves over a smaller area of the fin structure.

The heat exchange between the flow chamber or respectively the first fluid and the heat transfer chamber, which is assisted by means of the thermoelectric temperature-control system or respectively the Peltier element, can be configured in any desired manner on the transfer chamber side. The heat transfer chamber can be realized for example by a solid body, which exchanges heat with the flow chamber or respectively with the first fluid.

It is also conceivable that the heat transfer chamber is able to be flowed through by a second fluid and is delimited by a tube, wherein the thermoelectric temperature-control system, in particular the Peltier element, is arranged between the fin structure and the tube. The heat transfer chamber, which is delimited by the tube, is preferably fluidically separated here from the flow chamber. Here, the second fluid can be a different fluid from the first fluid.

Embodiments are also to be considered, in which the heat transfer chamber is able to be flowed through by a second fluid and is delimited by a sheet metal structure, wherein the thermal temperature-control system, in particular the semiconductors of the Peltier element, are arranged between the fin structure and the sheet metal structure. Here, also, the heat transfer chamber which is delimited by the sheet metal structure, is preferably fluidically separated from the flow chamber. The sheet metal structure advantageously has an uneven, for example corrugated, shape and is able to be flowed through by the second fluid. The sheet metal structure can therefore in particular also be configured as such a fin structure, which is arranged in the heat transfer chamber.

It is conceivable, in particular, to connect the sheet metal structure to the semiconductors of the Peltier element in an analogous manner to the fin structure, and/or to contact the semiconductors in an analogous manner. This means that on the side of the sheet metal structure facing the Peltier element, in particular facing the semiconductors, several such connecting structures as provided. Here, the sheet metal structure is provided with the base layer, wherein on the side of the base layer, facing away from the sheet metal structure, the connecting layer is applied for the electrical contacting of such a p-type semiconductor to such an n-type semiconductor.

The base layer preferably has such a flexibility that the base layer retains its electrical insulation characteristic, or respectively remains on the fin structure, during operation of the heat exchanger, in particular of the thermoelectric temperature-control system, particularly preferably during the entire duration of operation of the heat exchanger. Here, attention is to be paid on the one hand to the flexibility of the fin structure, in particular in the region of the associated connecting layer, and on the other hand to the flexibility of a component to which the semiconductors are connected on the side facing away from the fin structure. The flexibility of the base layer is therefore preferably adapted in this respect to the flexibility of the fin structure and/or of the component. Here, the flexibility of the base layer depends in particular on the thickness of the raw material on which the fin structure is based, or respectively of the material from which the fin structure is produced. This can lie for example in the range of 30 μm to 200 μm. The same applies to said component.

Preferably, the same applies to the flexibility of the connecting layer. This means that the connecting layer is matched as regards its flexibility, as explained above, to the fin structure and/or to the component. In particular, the connecting layer can be matched as regards its flexibility to the associated base layer, so that the connection between the connecting layer and the associated base layer is retained during the operation of the heat exchanger, particularly preferably during the entire duration of operation of the heat exchanger, and/or that the connecting layer remains electrically conductive.

When both the fin structure and also the component are embodied so as to be flexible, then for example a maximum displacement of approximately 5 μm to 50 μm is to be compensated through flexible bending. When the fin structure or the component is rigid, for example is constructed as a tube, then for example a maximum displacement of 100 μm to 1000 μm is to be compensated through flexible bending. The base layer and/or the connecting layer is/are therefore to be matched accordingly as regards their flexibility. This matching is advantageously such that the flexibility permits these deflections, without the above-mentioned characteristics of the base layer or respectively of the connecting layer being lost.

The connecting layer can be produced basically from any desired material, in so far as the connecting layer has a sufficiently high electrical conductivity for the electrical contacting of the associated semiconductors. In particular, it is conceivable to produce the connecting layer from a metal or from a metal alloy. It is advantageous here if the connecting layer has an electrical conductivity which is higher than the conductivity of the fin structure. The connecting layer therefore has in particular an electrical conductivity which is higher than the electrical conductivity or aluminium or respectively of its alloys.

The connecting layer can have basically any desired form here. It is particularly preferred here if the connecting layer has a thickness extending from the side facing the base layer to the side facing away from the base layer, which is at least 10× smaller than a width running transversely to the thickness, and/or than a length of the connecting layer running transversely to the thickness and transversely to the width. In other words, the connecting layer is configured so as to be as thin and wide as possible. The thin configuration of the connecting layer leads here to a correspondingly advantageous flexibility of the connecting layer, in order in particular to equalize thermal stresses. The wide configuration of the connecting layer provides, at the same time, for a high electrical conductivity within the connecting layer, in order to produce a sufficiently high electrical connection between the associated semiconductors.

The base layer preferably has a thermal conductivity of at least 1 W/m K. Embodiments are preferred, in which the base layer has a thermal conductivity of at least several W/m K, for example between 1 and 50 W/m K. Therefore, the heat exchange between the associated semiconductors and the fin structure is not reduced or is reduced relatively little. Here, in the case of a chemical and/or physical connection with the fin structure, the base layer preferably has a thermal conductivity between 1 W/m K and 10 W/m K, in particular between 1 W/m K and 5 W/m K. Such a base layer, formed by oxidation, in particular anodization, or respectively reduction-oxidation reaction, preferably has a thermal conductivity between 1 W/m K and 50 W/m K, in particular between 10 W/m K and 50 W/m K.

The base layer is preferably thinner than 100 μm, in particular between 1 μm and 100 μm thick. Embodiments are particularly preferred, in which the base layer has a thickness between 30 μm and 50 μm.

It is preferred if between the respective connecting layer and the associated semiconductors no further components are arranged, with the exception of components which are necessary, if applicable, for the mechanical connecting of the connecting layer to the semiconductors. This means that a direct mounting of the semiconductors on the respective connecting layer is preferred. Therefore, in addition to a better heat exchange between the temperature-control system and the fin structure or respectively the flow chamber, a less rigid construction is produced. The less rigid construction leads to an improved reduction of thermally caused loads and therefore to an improvement in the thermomechanical stability.

In an analogous manner hereto, it is preferred if the respective connecting structure is mounted directly on the base layer and/or if the fin structure is provided directly with the base layer.

The fin structure can basically be configured and/or formed in any desired manner. Preferably, the fin structure is produced from a sheet metal part and preferably in one piece. In particular, the sheet metal part can be produced by shaping to the fin structure. In addition to a favourably priced production, this leads to an improvement in the thermal conductivity and a reduction in weight.

Embodiments are preferred in which the fin structure has first and second base sections, which are spaced apart from one another and are connected to one another by legs of the fin structure. Here, the respective first base section is provided with the base layer, whereas the second base sections are arranged on the side of the first base sections facing away from the temperature-control system. In particular, the first base sections and the second base sections can run in a parallel manner.

Adjacent first and second base sections are preferably connected to one another by respectively one leg. Here, adjacent first and second base sections have respectively a shared such leg, wherein two such legs project from the respective base section, which connect the base section to the two adjacent base sections. This, of course, does not imperatively apply to the outermost base sections.

Variants prove to be advantageous, in which the first base sections are spaced apart from one another. In addition, variants are advantageous in which the second base sections are spaced apart from one another. This leads respectively to an improved reduction of thermally caused loads, in particular stresses, and therefore to an improved thermomechanical stability of the fin structure and consequently of the temperature-control system and of the heat exchanger.

According to advantageous variants, the adjacent legs of the fin structure are arranged in an inclined manner to one another. Such a configuration of the fin structure leads to an increased flexibility and elasticity of the fin structure and therefore to an improved reduction of thermal loads, in particular stresses. The legs projecting from the respective base section can face one another here, and/or can form an acute angle with the associated base section.

It shall be understood that in addition to the heat exchanger, an assembly of such a fin structure and of such a temperature-control system, in which the semiconductors of the temperature-control system are mounted on the fin structure via such connecting structures, also belongs to the scope of this invention.

Further important features and advantages of the invention arise from the subclaims, from the drawings and from the associated figure description with the aid of the drawings.

It shall be understood that the features mentioned above and to be explained further below are able to be used not only in the respectively indicated combination, but also in other combinations or in isolation, without departing from the scope of the present invention.

Preferred example embodiments of the invention are illustrated in the drawings and are explained further in the following description, wherein the same reference numbers refer to identical or similar or functionally identical components.

### BRIEF DESCRIPTION OF THE DRAWINGS

There are shown, respectively diagrammatically,

FIG. 1 a longitudinal section through a heat exchanger,

FIG. 2 a cross-section through the heat exchanger,

FIG. 3 a view onto the heat exchanger in another example embodiment,

FIG. 4 the section of FIG. 1 in a further example embodiment,

FIG. 5 the view of FIG. 4 in another example embodiment.

### DETAILED DESCRIPTION

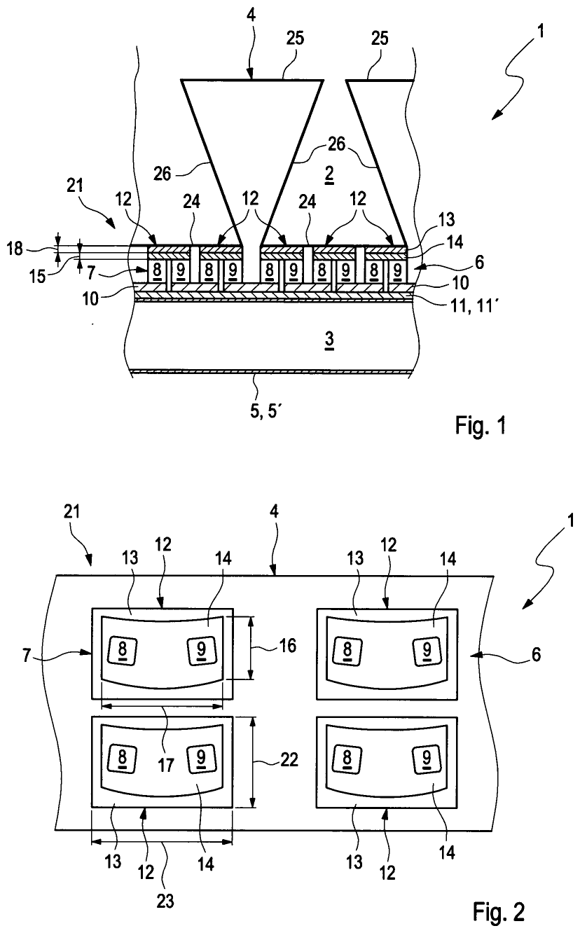

In FIG. 1 a heat exchanger 1 is shown, which can come into use in a motor vehicle which is otherwise not shown. The heat exchanger 1 has a flow chamber 2 and a heat transfer chamber 3 which is fluidically separated from the flow chamber 2. The flow chamber 2 is flowed through by a first fluid, whereas the heat transfer chamber 3 is flowed through by a second fluid. A heat exchange occurs here in the heat exchanger 1 between the first fluid and the second fluid. In the flow chamber 2 a fin structure 4 is arranged which, in the longitudinal section which is shown, has an omega-like shape. The heat transfer chamber 3 is delimited by a tube 5, which also delimits the flow chamber 2 or is arranged in the flow chamber 2. A thermoelectric temperature-control system 6 with a Peltier element 7 is arranged between the fin structure 4 and the tube 5 or respectively the heat transfer chamber 3. The Peltier element 7 has a plurality of p-doped p-type semiconductors 8 and n-doped n-type semiconductors 9 which, in the example which is shown, are arranged alternately along the tube 5. For the electrical connecting of the semiconductors 8, 9 in the manner of the Peltier element 7, respectively a p-type semiconductor 8 and an n-type semiconductor 9 are electrically connected to one another here. On the side of the semiconductors 8, 9 facing the tube 5, which is configured in particular as a flat tube 5′, associated p-type semiconductors 8 and n-type semiconductors 9 are electrically connected to one another by means of an electrically conductive connecting element 10. As the tube 5 is electrically conductive and is made for example from a metal, an electrically insulating plate 11 is arranged between the tube 5 and the connecting elements 10 in order to prevent short-circuits between the connecting elements 10. The tube 5 is entirely covered here on the side facing the semiconductors 8,9 by the plate 11, which can be, for example, a ceramic plate 11′.

On the side of the fin structure 4 facing the Peltier element 7 and the semiconductors 8,9 a plurality of connecting structures 12 are provided. The respective connecting structure 12 has an electrically insulating base layer 13 and an electrically conductive connecting layer 14. In the example which is shown, the base layer 14 is configured as a separate element and is mounted on the fin structure 4. Such a connecting layer 14 is applied, in particular connected to the base layer 13 in a materially bonded manner, on the side of the respective base layer 13 facing away from the fin structure 4 and therefore on the side of the respective base layer 13 facing the semiconductors 8, 9. The electrically conductive connecting layer 14 connects respectively one such p-type semiconductor 8 and one such n-type semiconductor 9 electrically to one another. Here, the connecting structures 12 are spaced apart from one another, so that the respective semiconductor pair, i.e. one such p-type semiconductor 8 and one such associated n-type semiconductor 9, is associated with one such connecting structure 12. On the side facing the fin structure 4, the semiconductors 8, 9 of the Peltier element 7 are therefore electrically contacted to one another by means of the connecting structure 12 and are electrically insulated with respect to the metalliferous fin structure 4.

The associated semiconductors 8, 9 are mounted on the associated connecting layer 14, such that the semiconductors 8, 9 are mechanically connected to the fin structure 4 via the connecting structure 12. The elastic and flexible fin structure 4 is therefore used in the Peltier element 7 for the compensation and reduction of thermal stresses which can occur during the operation of the heat exchanger 1, in particular of the Peltier element 7.

Here, the base layer 13 can be produced by an oxidation, a reduction-oxidation reaction, in particular by anodizing, on the fin structure 4, or can be applied by means of external application of a layer through chemical and/or physical bonding on the fin structure 4.

In FIG. 2 a cross-section is shown through the heat exchanger 1 in the region between the connecting layers 14 and the associated semiconductors 8, 9. In FIG. 2, firstly it can be seen that the Peltier element 7, in addition to the adjacent semiconductors 8, 9 along the tube 5, also has semiconductors 8, 9 spaced apart transversely hereto, which are also electrically contacted via such connecting structures 12 and are mounted on the fin structure 4. It can be seen in addition from FIG. 2 and FIG. 1 that both the base layer 13 and also the connecting layer 14 are configured so as to be thin. This means, in the connecting layer 14, that a thickness 15 of the connecting layer 14 extending from the side facing the base layer 13 to the side facing away from the base layer 13, or a connecting layer thickness 15, is distinctly smaller than a connecting layer width 16 running transversely to the connecting layer thickness 15, and a connecting layer length 17 running transversely to the connecting layer thickness 15 and transversely to the connecting layer width 16. This thin form of the connecting layer 14 provides, at the same time, for a flexible construction and sufficient electrical conductivity of the connecting layer 14. The thickness 15 of the connecting layer 14 here is preferably a few μm, for example 1 to 100 μm.

The base layer 14 also has a base layer thickness 18, which is distinctly smaller than a base layer width 22 and a non base layer length 23, which run parallel to the corresponding dimensions of the connecting layer 14. The base layer thickness 18 here is preferably between 1 μm and 100 μm, in particular between 30 μm and 50 μm. The base layer 13 is greater here than the associated connecting layer 14 and has in particular a greater cross-section than the associated connecting layer 14. Hereby, an improved electrical insulation of the connecting structure 14 with respect to the fin structure 4 is achieved, in particular short-circuits, for example caused by edge flaws and/or positioning inaccuracies, are prevented or at least reduced.

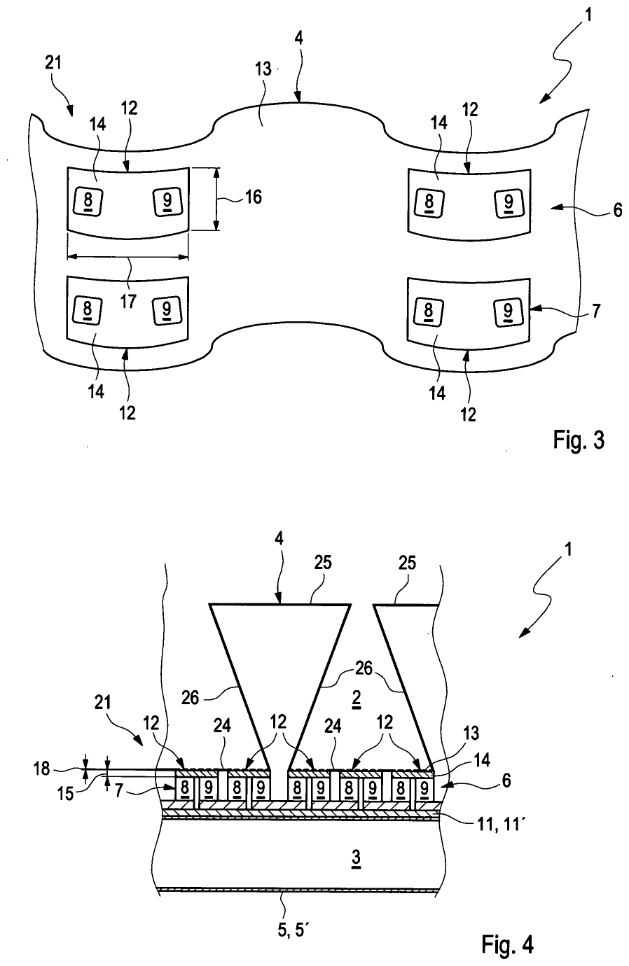

In FIG. 3 a similar view to in FIG. 2 is illustrated, wherein the view in FIG. 3 is slightly inclined and accordingly illustrated three-dimensionally. In FIG. 3 an example embodiment is illustrated which differs substantially from the example embodiment shown in FIG. 2 in that the fin structure 4 does not have an omega-shaped configuration, but rather is configured in a corrugated manner. Here, in the region of adjacent wave troughs of the fin structure 4, configured in a corrugated manner, facing the semiconductors 8, 9, such semiconductors 8, 9 are arranged and such associated connecting structures 12 are provided, which electrically contact associated semiconductors 8, 9, electrically insulate them from the fin structure 4 and connect them mechanically to the fin structure 4. In addition, in this example embodiment one such shared base layer 13 is provided for at least two such connecting layers 14, wherein in the example which is shown one such shared base layer 13 is associated with all connecting structures 14, which base layer extends over the entire visible surface of the fin structure 4 facing the semiconductors 8, 9. This means that the fin structure 4 is not respectively provided locally with a base layer 13 associated with the respective connecting layer 14, but rather is provided entirely with one such base layer 13, which is associated with at least two such connecting layers 14, in particular all connecting layers 14 and insulates these electrically with respect to the fin structure 4. The fin structure 4 can be provided here in a simplified manner with one such shared base layer 13, compared to several individual base layers 13.

Another example embodiment of the heat exchanger 1 is illustrated in FIG. 4. The heat exchanger 1 of FIG. 4 differs from the heat exchanger 1 shown in FIG. 1 substantially through the configuration of the base layers 13 of the respective connecting structure 12. The base layers 13 are illustrated in dashed lines in FIG. 4 and are a component part of the fin structure 4. This means that the base structure 13 of the respective connecting structure 12 is an integral component part of the fin structure 4. The integral configuration of the base structure 13 on the fin structure 4 takes place preferably through an oxidation or a reduction-oxidation reaction of the fin structure 4. This means that the respective base layer 13 is realized by a corresponding treatment of the fin structure 4. Hereby, a particularly advantageous matching or similarity exists between the flexibility and/or the thermal expansion- or respectively contraction behaviour of the base layer 13 and of the fin structure 4. Here, for better illustration, the respective base layer 13 is illustrated over the entire thickness of the fin structure 4, which, however, does not necessarily have to be the case. This means that the respective base layer 13 can have a base layer thickness 18 which is smaller than the thickness of the fin structure 4 in the associated region, wherein the base layer thickness 18 is preferably smaller than the thickness of the fin structure 4 in the associated region. Also in this example embodiment, the base layer thickness 18 is preferably between 1 μm and 100 μm, preferably between 30 μm and 50 μm.

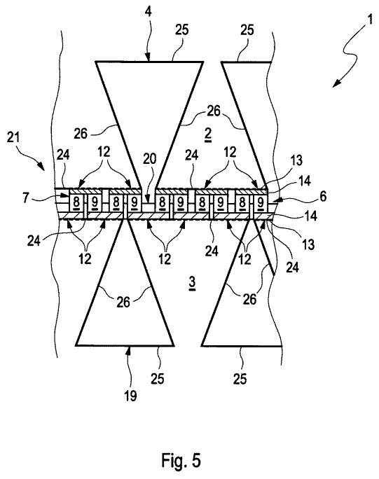

A further example embodiment of the heat exchanger 1 is illustrated in FIG. 5. This example embodiment differs from the example embodiment shown in FIG. 4 in particular in that in the heat transfer chamber 3 a sheet metal structure 19 is arranged which, like the fin structure 4 is configured in a fin-like manner and has an omega shape. The sheet metal structure 19 delimits the heat transfer chamber 3 here and is able to be flowed through by the second fluid. The heat transfer chamber 3 and the flow chamber 2 are separated fluidically and thermally by a separating structure 20, wherein the separating structure 20 extends between adjacent semiconductors 8, 9 of the Peltier element 7.

It can be seen in addition from FIG. 5 that such connecting structures 12 are also provided between the semiconductors 8, 9 and the sheet metal structure 19, wherein the respective connecting structure 12, via the connecting layer 14 and the base layer 13, electrically contacts associated semiconductors 8, 9, electrically insulates them from the sheet metal structure 19 and connects them mechanically and thermally to the sheet metal structure 19. This means that on both sides of the semiconductors 8, 9 or respectively of the Peltier element 7, such connecting structures 12 come into use for the electrical contacting of the semiconductors 8, 9 and for the electrical insulating of the semiconductors 8, 9 with respect to the fin structure 4 or respectively the sheet metal structures 19, and for the mechanical connecting of the semiconductors 8, 9 to the fin structure 4 or respectively to the sheet metal structure 19. Hereby, a configuration of the heat exchanger is produced which is particularly stable with respect to thermal loads.

In the examples which are shown, the at least one base layer 13 and the connecting layers 14 are matched with regard to their flexibility to that of the fin structure 4, in particular in the region of the connecting structure 12, and/or to the component 5, 19 arranged on the side of the semiconductors 8, 9 facing away from the base layer 13, here therefore to the tube 5 or respectively to the sheet metal structure 19. This match depends here in particular on the thickness of the fin structure 4 or respectively of the component 5, 19 and/or on the material from which the fin structure 4 or respectively the component 5, 19 is produced. In the case of the rigid tube 5 and the flexible fin structure 4, the flexibility is respectively such that displacements of approximately 5 μm to 50 μm are compensated through flexible bending without the electrically insulating characteristic of the base layer 13 and the electrically conductive characteristic of the connecting layer 14 being lost and without the corresponding connections loosening. In the case of the flexible sheet metal structure 19 and the flexible fin structure 4, the flexibility of base layer 13 and connecting layer 14 is such that displacements of approximately 100 μm to 1000 μm are compensated through flexible bending without the electrically insulating characteristic of the base layer 13 and the electrically conductive characteristic of the connecting layer 14 being lost and without the corresponding connections loosening. The fin structure 4 forms, together with the such connecting structures 12 and the associated semiconductors 8, 9 of the Peltier element 7, an assembly 21, wherein such an assembly can be seen in FIGS. 2 and 3.

The fin structures 4 shown in FIGS. 1, 2, 4 and 5 have respectively first base sections 24, which are spaced apart from one another and are respectively provided with such a base layer 13. The respective fin structure 4 has, in addition, second base sections 25, which are arranged on the side of the first base sections 24 facing away from the temperature-control system 6 and are spaced apart therefrom. Two legs 26 project from the respective base section 24, 25, which legs connect the first base sections 24 to the adjacent second base sections 25 and vice versa. Therefore, one such leg 26 projects from the respective first base section 24, which also projects form the adjacent second base section 25. In the example which is shown, the legs 26 run in an inclined manner to the associated base sections 24, 25. In addition, the legs 26 projecting form the respective base section 24, 25 face one another and form an acute angle with this base section 24, 25.

In the example shown in FIG. 5, the sheet metal structure 19 is configured in an analogous manner to the fin structure 4. This means that the sheet metal structure 19 likewise has first and second base sections 24, 25 which are connected to one another by legs 26 in the manner previously described, wherein the first base sections 24 are respectively provided with such a base layer 13.

1. A heat exchanger, comprising:
a flow chamber able to be flowed through by a first fluid;
a fin structure arranged in the flow chamber and able to be flowed through by the first fluid;
a heat transfer chamber for an exchange of heat with the first fluid;
a thermoelectric temperature-control system, arranged between the fin structure and the heat transfer chamber, for heat transmission between the heat transfer chamber and the flow chamber;
the temperature-control system including at least one Peltier element with a plurality of p-doped p-type semiconductors and a plurality of n-doped n-type semiconductors electrically contacting one another;
wherein on a side of the fin structure facing the at least one Peltier element a plurality of connecting structures are arranged;
a respective connecting structure including an electrically insulating base layer and an electrically conductive connecting layer;
the fin structure including the base layer;
the connecting layer applied on a side of the base layer facing away from the fin structure;
one such p-type semiconductor and one such n-type semiconductor mounted, for the electrical contacting of these semiconductors, on the connecting layer on a side of the connecting layer facing away from the base layer;
wherein the fin structure is provided with the base layer via oxidation.

2. The heat exchanger according to claim 1, wherein the fin structure is provided with the base layer via a reduction-oxidation reaction.

3. The heat exchanger according to claim 1, wherein the base layer is provided via at least one of an oxidation and a reduction-oxidation reaction of the fin structure.

4. The heat exchanger according to claim 1, wherein the base layer is anodized onto the fin structure.

5. The heat exchanger according to claim 1, wherein the heat transfer chamber is able to be flowed through by a second fluid and is delimited by a tube, and wherein the thermoelectric temperature-control system is arranged between the fin structure and the tube.

6. The heat exchanger according to claim 1, wherein the heat transfer chamber is able to be flowed through by a second fluid and is delimited by a sheet metal structure, and wherein the thermoelectric temperature-control system is arranged between the fin structure and the sheet metal structure.

7. The heat exchanger according to claim 1, wherein the base layer has a greater cross-sectional area than an associated connecting layer.

8. The heat exchanger according to claim 1, wherein the base layer is associated with at least two connecting layers.

9. The heat exchanger according claim 1, wherein the base layer has a flexibility matched to at least one of a flexibility of the fin structure and a flexibility of a component arranged on a side of the semiconductors facing away from the base layer.

10. The heat exchanger according to claim 1, wherein the connecting layer has a flexibility matched to at least one of a flexibility of the fin structure, a flexibility of the base layer, and to a flexibility of a component arranged on a side of the semiconductors facing away from the base layer.

11. The heat exchanger according to claim 1, wherein the base layer has a thermal conductivity of at least 1 W/(mK).

12. The heat exchanger according to claim 1, wherein the connecting layer has a connecting layer thickness extending from a side facing the base layer to the side facing away from the base layer, which is at least ten times smaller than at least one of a width of the connecting layer extending transversely to the connecting layer thickness and a length of the connecting layer extending transversely to the connecting layer thickness and transversely to the width.

13. The heat exchanger according to claim 1, wherein the base layer has a base layer thickness of 1 μm to 100 μm.

14. The heat exchanger according to claim 1, wherein:
the fin structure has a plurality of first base sections including the base layer;
the fin structure has a plurality of second base sections arranged spaced apart from the plurality of first base sections on a side of the plurality of first base sections facing away from the temperature-control system;
the fin structure includes a plurality of legs projecting from the base sections, the plurality of legs connecting the base sections to one another; and
the plurality of legs projecting from a respective base section extend in an inclined manner to one another.

15. The heat exchanger according to claim 14, wherein the fin structure is provided in a single piece and structured from a metal sheet.

16. An assembly comprising the fin structure and the temperature-control system of the heat exchanger according to claim 1, wherein the semiconductors of the temperature-control system are mounted on the fin structure and electrically contact one another via the plurality of connecting structures.

17. The heat exchanger according to claim 7, wherein the base layer is associated with at least two connecting layers.

18. The heat exchanger according to claim 9, wherein the connecting layer has a flexibility matched to at least one of i) a flexibility of the fin structure, ii) a flexibility of the base layer, and iii) a flexibility of a component arranged on a side of the semiconductors facing away from the base layer.

19. The heat exchanger according to claim 12, wherein the base layer has a base layer thickness of 1 μm to 100 μm.

20. An assembly comprising:
a fin structure through which a first fluid is flowable;
a thermoelectric temperature-control system including at least one Peltier element with a plurality of p-doped p-type semiconductors and a plurality of n-doped n-type semiconductors electrically contacting one another;
a plurality of electrically insulating base layers arranged on the fin structure;
a plurality of electrically conductive connecting layers arranged on a side of the plurality of base layers facing away from the fin structure;
a plurality of connecting structures respectively including a base layer of the plurality of base layers and a connecting layer of the plurality of connecting layers, the plurality of connecting structures arranged on a side of the fin structure facing the at least one Peltier element; and
a p-type semiconductor of the plurality of p-type semiconductors and a n-type semiconductor of the plurality of n-type semiconductors arranged on a side of the connecting layer facing away from the base layer such that the p-type semiconductor and the n-type semiconductor are electrically contactable;
wherein the plurality of p-type semiconductors and the plurality of n-type semiconductors are mounted on the fin structure and electrically contact one another via the plurality of connecting structures; and
wherein the base layer is an oxidation base layer.
